(19) United States
(12) Patent Application Publication
(10) Pub. No.: US 2025/0291140 A1
(43) Pub. Date: Sep. 18, 2025

(54) PHOTONIC DEVICE WITH EXTENDED METAL LAYER AND METHODS

(71) Applicant: II-VI Delaware, Inc., Wilmington, DE (US)

(72) Inventors: Yao Sun, Shanghai (CN); Po Dong, Shanghai (CN); Juan Hu, Shanghai (CN); Andrei Kaikkonen, Shanghai (CN); Michael Kossey, Wilmington, DE (US); Hongju Xu, Shanghai (CN); Neo Si, Shanghai (CN); Gilberto Salamanca, Shanghai (CN); Shanshan Zeng, Shanghai (CN); Linjie Zhou, Shanghai (CN)

(21) Appl. No.: 18/655,921

(22) Filed: May 6, 2024

(30) Foreign Application Priority Data
Mar. 14, 2024 (CN) 2024102956367

(51) Int. Cl. G02B 6/42

(52) U.S. Cl. CPC G02B 6/4277; G02B 6/4283

(57) ABSTRACT

A photonic device includes a substrate, photonic integrated circuit structures on the substrate, and a redistribution structure over and coupled to the one or more photonic integrated circuit structures. The redistribution structure includes one or more metal layers and one or more dielectric layers. Pad and edge connect openings through a first dielectric layer of the one or more dielectric layers expose a first metal layer of the one or more metal layers at a top side of the redistribution structure. Edge connect openings are positioned such that at least a portion of a perimeter of the photonic device is closer to the edge connect openings than to the pad openings. The edge connect openings may be diced and electrical connections made via the first metal layer and/or diced portions along a sidewall of the photonic device.

### CLAIM OF PRIORITY AND CROSS-REFERENCE TO RELATED APPLICATIONS/INCORPORATION BY REFERENCE

This patent application claims priority to Chinese Application No. 2024102956367, filed Mar. 14, 2024, the above-identified application is hereby incorporated herein by reference in its entirety.

### TECHNICAL FIELD

Aspects of the present disclosure are related to photonic integrated circuit (PIC) devices and methods of manufacturing photonic integrated circuit (PIC) devices.

### BACKGROUND

Silicon photonics photonic integrated circuits (Siph PICs) are usually fabricated using thick, e.g., about 750 micrometers (μm), silicon-on-insulator (SOI) wafers. In such fabricated wafers, the functional devices (e.g., optical and electronic devices) of the Siph PICs are located within the first few micrometers (μm) from a top surface of the Siph PIC, which may include semiconductor layers (Si, Ge, etc.), metal layers, and dielectric layers. The semiconductor layers, metal layers, and dielectric layers may form various photonic and/or electronic integrated circuit structures. In addition, the metal and dielectric layers may provide electrical paths for the photonic and/or electronic integrated circuit structures. The remaining micrometers beneath the above-mentioned layers (e.g., the other >95% of the wafer) may include no metal layers and thus limit opportunities for providing electrical connections to functional devices of Siph PIC devices.

Further limitations and disadvantages of conventional and traditional approaches will become apparent to one of skill in the art, through comparison of such systems with some aspects of the present disclosure as set forth in the remainder of the present application with reference to the drawings.

### BRIEF SUMMARY OF THE DISCLOSURE

Shown in and/or described in connection with at least one of the figures, and set forth more completely in the claims, are photonic devices and associated processes for manufacturing photonic devices. Conventional photonic devices may provide electrical connection only through pads along a front side of photonic device using wirebonding or flipchip bonding. Various embodiments of the present disclosure may permit making electrical connection via metal or other conductive material along sidewalls and/or backsides of the photonic devices.

For example, photonic devices per some embodiments of the present disclosure may include one or more metal layers that extend to at least dicing streets of a wafer of the photonic devices. Dicing or singulation of such wafers along the dicing streets in order to separate or singulate the photonic devices from one another may expose one or more metal layers along sidewalls of the photonic devices. Such exposed metal layers may enable making electrical connections via at least one sidewall of the diced photonic device and/or may enable providing the photonic devices with external electrical connections having better electrical properties such as, for example, greater current capacity, greater current stability, greater voltage capacity, less electrical resistance, etc. compared to conventional techniques.

These and other advantages, aspects and novel features of the present disclosure, as well as details of illustrated embodiments thereof, will be more fully understood from the following description and drawings.

### BRIEF DESCRIPTION OF THE DRAWINGS

Various features and advantages of the present disclosure may be more readily understood with reference to the following detailed description taken in conjunction with the accompanying drawings, wherein like reference numerals designate like structural elements.

FIG. 1 depicts a wafer comprising photonics devices prior to dicing and separating the photonic devices.

FIG. 2A depicts a plan view of a photonic device of the wafer of FIG. 1 prior to dicing the wafer.

FIG. 2B depicts a plan view of the photonic device of FIG. 2A after dicing the wafer.

FIG. 3A depicts a cross section of a perimeter portion of the photonic device of FIG. 2A prior to dicing.

FIG. 3B depicts the cross section of the perimeter portion of FIG. 3A after dicing.

FIG. 3C depicts the cross section of the perimeter portion of FIG. 3B after extending the metal layer along a sidewall of the photonic device.

FIG. 3D depicts the cross section of the perimeter portion of FIG. 3C after extending the metal layer along a bottom side of the photonic device.

FIG. 4 depicts a flowchart for manufacturing photonic devices per the process of FIGS. 3A-3D.

FIG. 5A depicts a cross section of perimeter portions of two adjacent photonic devices during a wafer fabrication.

FIG. 5B depicts the cross section of the perimeter portions of FIG. 5A after forming a trench along a dicing street between the adjacent photonic devices.

FIG. 5C depicts a cross section of the perimeter portions of FIG. 5B after depositing a metal layer and patterning the metal layer via a lift-off process.

FIG. 5D depicts a cross section of the perimeter portions of FIG. 5C after dicing along the dicing street.

FIG. 5E depicts the cross section of the perimeter portion of FIG. 5D after extending the metal layer along a sidewall of the photonic device.

FIG. 5F depicts the cross section of the perimeter portion of FIG. 5E after extending the metal layer along a bottom side of the photonic device.

FIG. 6 depicts a flowchart for manufacturing photonic devices per the process of FIGS. 5A-5F.

### DESCRIPTION

The following discussion provides various examples of photonic integrated circuit (PIC) devices, silicon photonics photonic integrated circuit (Siph PIC) devices, and associated processes for manufacturing photonic devices. Such examples are non-limiting, and the scope of the appended claims should not be limited to the particular examples disclosed. In the following discussion, the terms “example” and “e.g.” are non-limiting.

The figures illustrate a general manner of construction. Descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “and/or” means any one or more of the items in the list joined by “and/or”. As an example, “x and/or y” means any element of the three-element set {(x), (y), (x, y)}. In other words, “x and/or y” means “one or both of x and y”. As another example, “x, y, and/or z” means any element of the seven-element set {(x), (y), (z), (x, y), (x, z), (y, z), (x, y, z)}. In other words, “x, y and/or z” means “one or more of x, y and z”.

The terms “comprises,” “comprising,” “includes,” and/or “including,” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements.

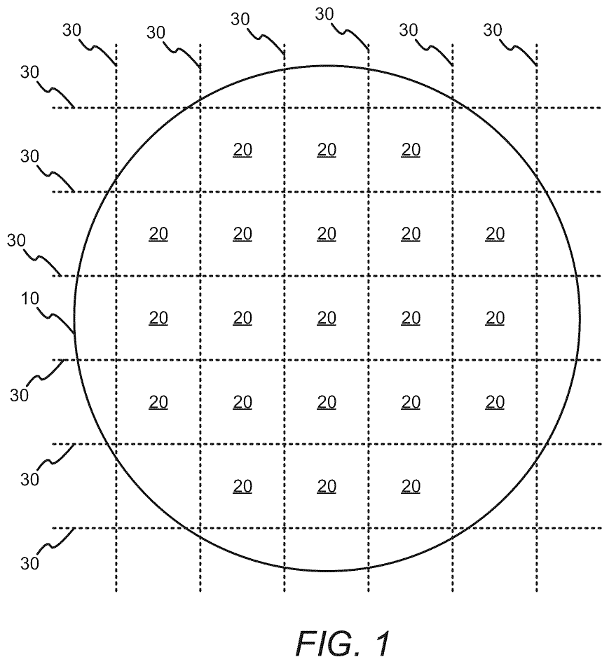

Turning now to FIG. 1, a wafer 10 is shown that comprises several photonic devices 20 (e.g., photonic integrated circuit (PIC) devices, silicon photonics photonic integrated circuit (Siph PIC) devices, etc.). In the interest of not distracting from other features of the disclosed embodiment, the wafer 10 of FIG. 1 is not drawn to scale and does not depict various features such as, for example, process control monitoring (PCM) regions, fiducial marks between reticles, etc. As shown, the photonic devices 20 may be arranged in an array of rows and columns separated by dicing streets 30. However, in other embodiments, the wafer 10 may arrange the photonic devices 20 in a different manner. In some embodiments, each photonic device 20 comprises a Siph PIC device. However, aspects of the present disclosure may also be applied to PIC devices and their manufacture. As such, the wafer 10 may include Siph PIC devices, PIC devices, or a combination of Siph PIC devices and PIC devices.

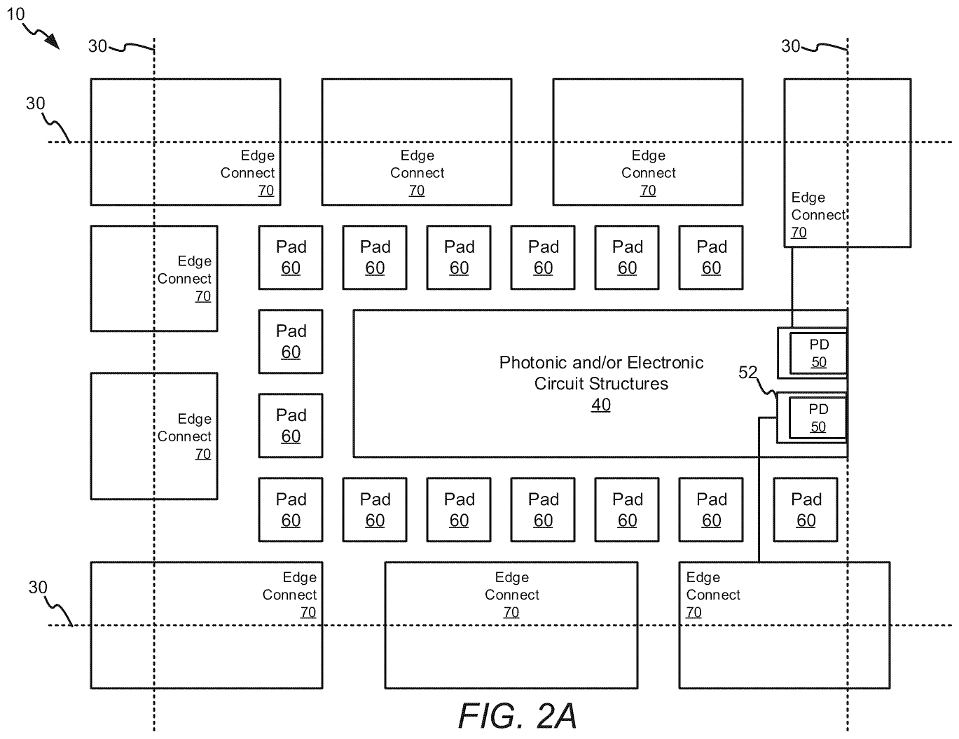

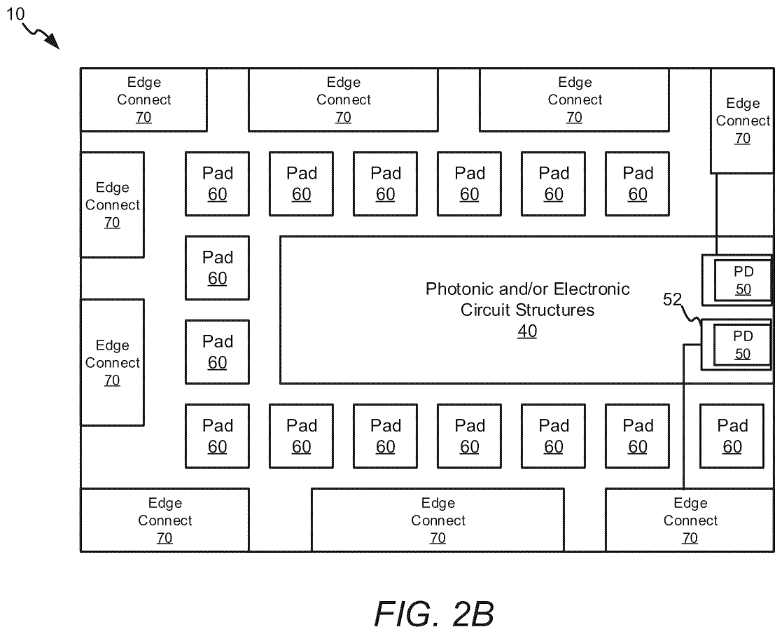

Aspects of a photonic device 20 of FIG. 1 are depicted in FIGS. 2A and 2B. In particular, FIG. 2A depicts a plan view of a photonic device 20 prior to dicing the wafer 10. FIG. 2B depicts a plan view of the photonic device of FIG. 2A after dicing the wafer 10 and separating the photonic device 20 of FIG. 1 from other photonic devices of the wafer 10.

As shown, the photonic device 20 may include photonic and/or electronic integrated circuit structures 40, pads 60, and edge connects 70. The photonic and/or electronic integrated circuit structures 40 may include at least one or more passive photonic structures or devices such as gratings, waveguides, etc. and/or one or more active photonic structures or devices 50 such as, for example, lasers, polarizers, phase shifters, photodetectors (PD). that generate, detect, transport, and process photons (i.e., light). The photonic and/or electronic integrated circuit structures 40 may also include one or more electronic integrated circuit structures such as transistors, diodes, resistors, capacitors, etc. that generally operate based on a flow of electrons.

As further shown in FIGS. 2A and 2B, a top side of the photonic device 20 may include pads 60 that provide an electronic interface for operatively coupling electronic integrated circuit structures and/or electronic interfaces of the photonic integrated circuit structures to other electronic components such as printed-circuit boards, interposers, integrated circuit (IC) chips, etc. To this end, the pads 60 may be implemented as wirebond pads via which wire bonds may operatively couple or bond the photonic device 20 to other electronic components. Such wirebond pads may be provided by forming holes or openings through one or more top dielectric layers of the photonic device 20 so as to expose an underlying metal layer of the photonic device 20. In some embodiments, the pads 60 may include lands, bumps, underbump metallization (UBM) layers, and/or other conductive interconnects that permit operatively coupling the electronic components of the photonic device 20 to other electronic components.

As also shown in FIGS. 2A and 2B, the top side of the photonic device 20 may include edge connects 70 along a perimeter or sidewall of the photonic device 20. The edge connects 70 may be formed in a similar manner as the pads 60. Moreover, the edge connects 70 may be formed closer to the perimeter or sidewall of the photonic device 20 than the pads 60. As explained in greater detail below, one or more metal layers of the photonic device 20 may be extended toward and/or beyond the dicing streets 30. As a result of extending one or more metal layers beyond the dicing streets 30 and exposing the one or more metal layers from a top side in a manner similar to pads 60, dicing the photonic device 20 from the wafer 10 may expose the one or more metal layers along the top side and sidewalls of the photonic device 20. In this manner, the dicing of the wafer 10 may provide the photonic device 20 with additional and/or alternative electrical connections along the sidewall of the photonic device 20.

Such electrical connections may improve the quality of the electrical connection of the photonic device 20. For example, such electrical connections may be used to provide better ground connections for shielding components 52 (e.g., metal layers) that wrap or at least partially surround photodetectors 50 and/or other photonic integrated circuit structures to prevent and/or reduce crosstalk between such components. Similarly, such electrical connections may be used to ground metal layers that provide internal EMI shielding components between photonic integrated circuit structures and/or electronic integrated circuit structures of the photonic device 20. Such electrical connections may also be used to ground external EMI shielding components of the photonic device 20 to shield photonic circuit components and/or electronic circuit components of the photonic device 20 from components that are external to the photonic device 20.

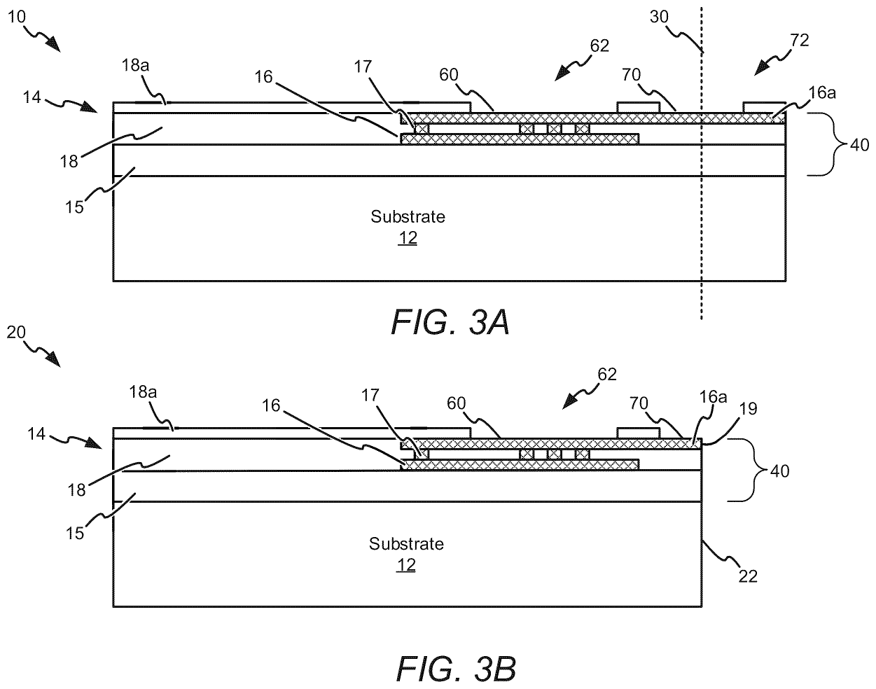

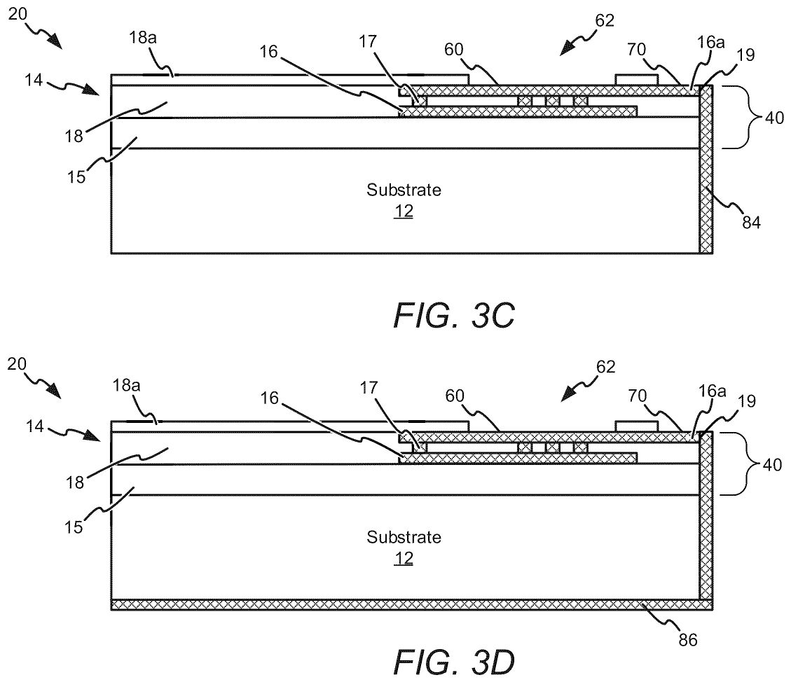

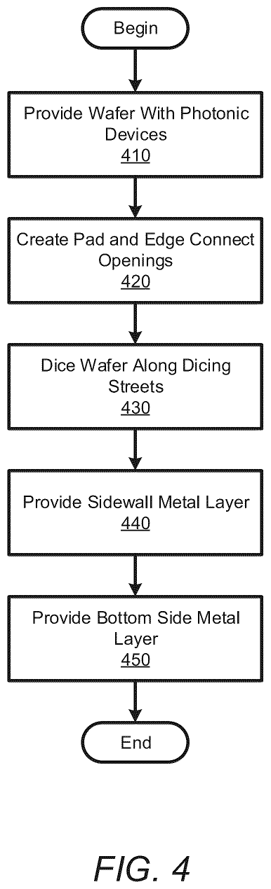

Aspects of an example manufacturing method 400 will be described with reference to the cross sections of FIGS. 3A-3D and the flowchart of FIG. 4. At 410, the manufacturing method 400 may include providing a wafer 10 with photonic devices 20. The photonic devices 20 may be arranged on the wafer 10 in an array as shown in FIG. 1. Moreover, the photonic devices 20 of the provided wafer 10 may include photonic and/or electronic integrated circuit structures 40. The photonic and/or electronic integrated circuit structures 40 may be formed from one or more semiconductor layers, one or more metal layers 16, and one or more dielectric layers 18. In particular, a top metal layer 16a of the one or more metal layers 16 may traverse the dicing streets 30 as shown in FIG. 3A.

The wafer 10 may be provided via various different techniques. In some embodiments, the manufacturing method 400 at 410 may perform all aspects of fabricating the photonic and/or electronic integrated circuit structures 40 such as its one or more semiconductor layers 15, one or more metal layers 16, and/or one or more dielectric layers 18 on a substrate 12 (e.g., a silicon-on-insulator substrate) to obtain the wafer 10 with photonic devices 20 as shown. In other embodiments, the wafer 10 may be received at various stages of fabrication (e.g., with one or more layers of the photonic and/or electronic integrated circuit structures 40 already formed) and the manufacturing method 400 at 410 may include completing the remaining fabrication steps to obtain the wafer 10 as shown.

As shown in FIGS. 3A-3D, the wafer 10 provided at 410 may include a substrate 12 having a top side, a bottom side opposite the top side, and a sidewall between the substrate top side and the substrate bottom side. In various embodiments, the substrate 12 comprises a silicon-on-insulator substrate upon which various layers (e.g., semiconductor layers 15, metal layers 16, dielectric layers 18, etc.) of the photonic and/or electronic integrated circuit structures 40 may be disposed.

As further shown, the photonic and/or electronic integrated circuit structures 40 may also include a redistribution structure 14. The redistribution structure 14 may include a top side, a bottom side opposite the top side, and a sidewall between the redistribution structure top side and the redistribution structure bottom side. In some embodiments, the redistribution structure 14 may be a build-up redistribution structure comprising alternating metal layers 16 and dielectric layers 18. The metal layers 16 may comprise conductive traces that route electrical signals of the electronic device and/or photonic active devices 50. To this end, the redistribution structure 14 may further include conductive vias 17, which extend through one or more dielectric layers 18 and couple one metal layer 16 to another metal layer 16.

At 420, the manufacturing method 400 may include creating openings in a top dielectric layer 18a of the redistribution structure 14 as shown in FIG. 3A. In particular, the manufacturing method 400 may generate pad openings 62 that expose pads 60 of a top metal layer 16a of the redistribution structure 14. Further, the manufacturing method 400 may generate edge connect openings 72 that expose edge connects 70 of the top metal layer 16a of the redistribution structure 14. To this end, the manufacturing method 400 may use photolithography techniques to develop a mask over the top dielectric layer 18a and etch the top dielectric layer 18a through openings in the mask which forms pad openings 62 and edge connect openings 72. In other embodiments, the manufacturing method 400 may use other techniques such as laser ablation to form openings 62, 72 in dielectric layer 18a.

The manufacturing method 400 at 430 may dice the wafer 10 along dicing streets 30. As shown in FIG. 3B, such dicing may cut through the top metal layer 16a and expose the top metal layer 16a at the redistribution structure sidewall. Various dicing techniques such as blade dicing, laser ablation dicing, and/or scribing may be used to separate the PIC devices 20 from the wafer 10. As a result of such dicing, a sidewall of the top metal layer 16a may be coplanar with the sidewall of the substrate 12. Moreover, the metal layer sidewall 19 may comprise a diced surface with different surface properties (e.g., rougher, blade marks, etc.) than one or more other surfaces of the top metal layer 16a. The dicing may also provide sidewall facets via which one or more photonic integrated circuit structures (e.g., photodetectors 50) of the photonic and/or electronic integrated circuit structures 40 may transmit and/or receive photons.

At 440, the manufacturing method 400 may provide a sidewall metal layer 84 along the sidewall of the photonic device 20. As shown in FIG. 3C, the sidewall metal layer 84 may cover and contact the metal layer sidewall 19 and the substrate sidewall. As such, the sidewall metal layer 84 may effectively extend the top metal layer 16a along the photonic device sidewall from the redistribution structure top side to substrate bottom side. To this end, the manufacturing method 400 may provide the sidewall metal layer 84 using various techniques such as applying conductive epoxy along the photonic device sidewall, applying a metal coating along the photonic device sidewall, etc. In this manner, the sidewall metal layer 84 may permit providing electrical connections to active devices and/or shielding components of the photonic device 20 via the photonic device sidewall.

Similarly, the manufacturing method 400 at 450 may provide a bottom side metal layer 86 along a portion of the substrate bottom side. In particular, the bottom side metal layer 86 may cover and contact a bottom side of the sidewall metal layer 84. As such, the bottom side metal layer 86 and the sidewall metal layer 84 may effectively extend the top metal layer 16a of the redistribution structure 14 to one or more portions of the photonic device bottom side. To this end, the manufacturing method 400 may provide the bottom side metal layer 86 using various techniques such as applying conductive epoxy along the substrate bottom side, applying a metal coating along the substrate bottom side, or applying the bottom side metal layer 86 via a wafer level sputtering from substrate bottom side, provided that sidewall metal layer 84 was created using methods described in the previous section. In this manner, the bottom side metal layer 86 may permit providing electrical connections to active devices and/or shielding components of the photonic device 20 via the photonic device bottom side.

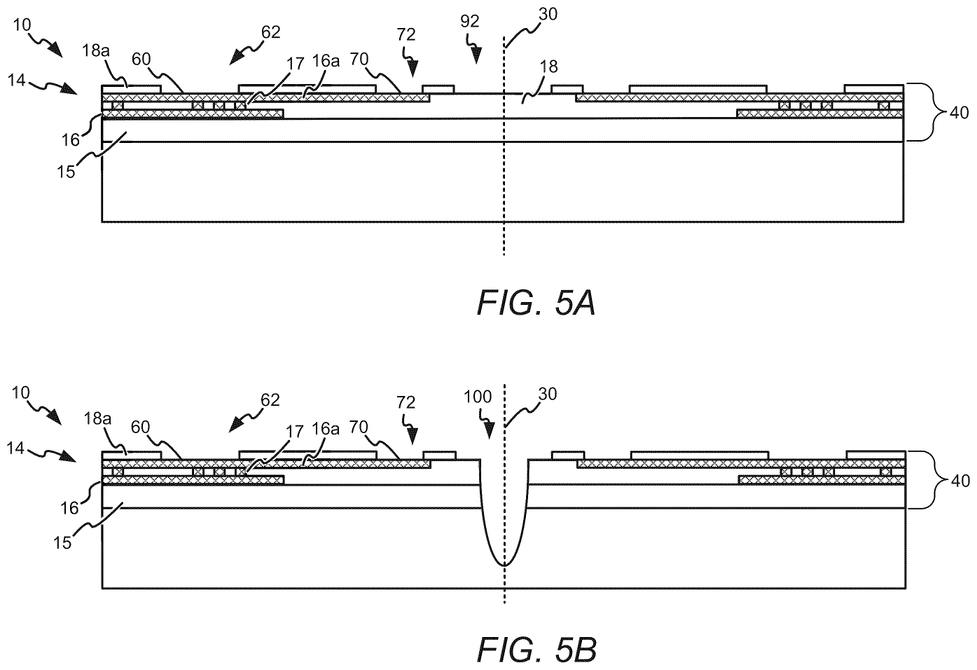

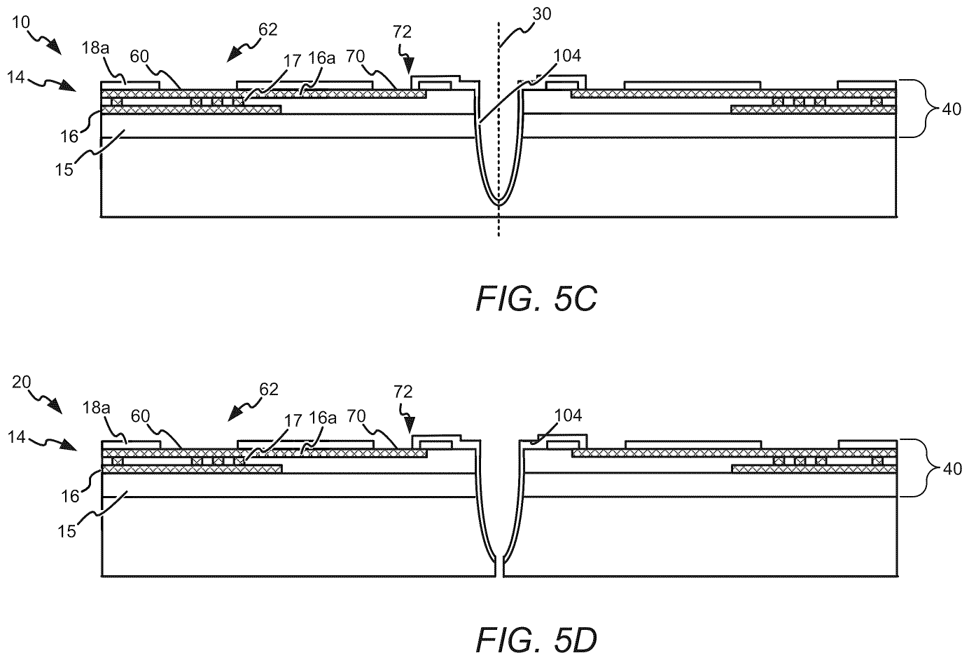

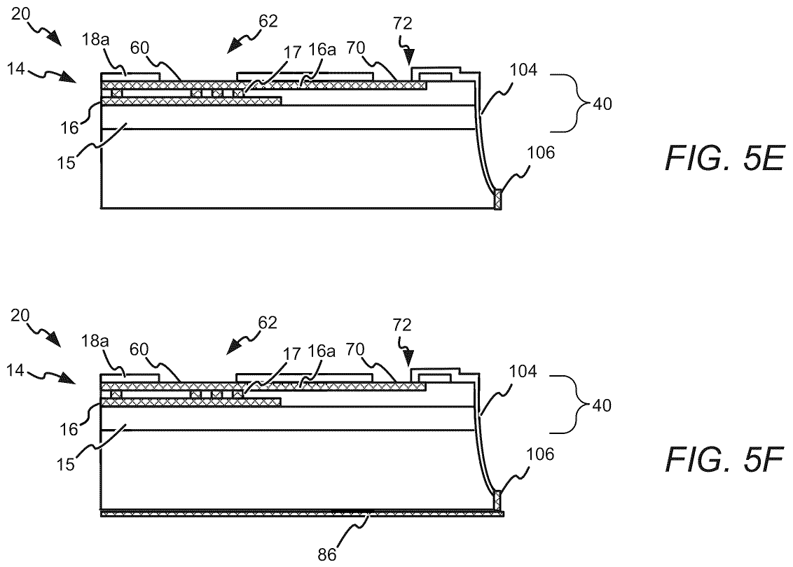

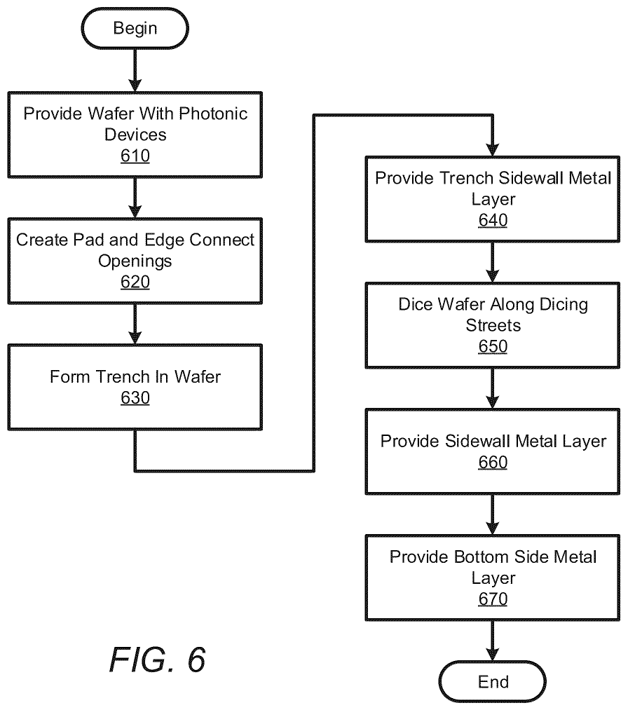

Aspects of another example manufacturing method 600 will be described with reference to the cross sections of FIGS. 5A-5F and the flowchart of FIG. 6. At 610, the manufacturing method 600 may include providing a wafer 10 with photonic devices 20. The photonic devices 20 may be arranged on the wafer 10 in an array as shown in FIG. 1. Moreover, the photonic devices 20 of the provided wafer 10 may include photonic and/or electronic integrated circuit structures 40. The provided wafer 10 may include a top metal layer 16a that extends pads 60 toward the dicing streets 30 as shown in FIG. 5A.

The wafer 10 may be provided via various different techniques. In some embodiments, the manufacturing method 600 at 610 may perform all aspects of fabricating the photonic and/or electronic structures 40 such as its one or more semiconductor layers 15, one or more the metal layers 16, and/or one or more dielectric layers 18 on a substrate 12 (e.g., a silicon-on-insulator substrate) to obtain the wafer 10 with photonic devices 20 as shown. In other embodiments, the wafer 10 may be received at various stages of fabrication (e.g., with one or more layers of the photonic and/or electronic integrated circuit structures 40 already formed) and the manufacturing method 600 at 610 may include completing the remaining fabrication steps to obtain the wafer 10 as shown.

As shown in FIGS. 5A-5F, the wafer 10 provided at 610 may include a substrate 12 having a top side, a bottom side opposite the top side, and a sidewall between the substrate top side and the substrate bottom side. In various embodiments, the substrate 12 comprises a silicon-on-insulator substrate upon which various layers (e.g., semiconductor layers, dielectric layers, etc.) of the photonic and/or electronic integrated circuit structures 40 may be disposed.

As further shown, the photonic and/or electronic integrated circuit structures 40 may also include a redistribution structure 14. The redistribution structure 14 may include a top side, a bottom side opposite the top side, and a sidewall between the redistribution structure top side and the redistribution structure bottom side. In some embodiments, the redistribution structure 14 may be a build-up redistribution structure comprising alternating metal layers 16 and dielectric layers 18. The metal layers may comprise conductive traces that route electrical signals of the electronic and/or photonic active devices 50. To this end, the redistribution structure 14 may further include conductive vias 17, which extend through one or more dielectric layers 18 and couple one metal layer 16 to another metal layer 16.

As shown at FIG. 5A, the manufacturing method 600 at 620 may include creating openings in a top dielectric layer 18a of the redistribution structure 14. In particular, the manufacturing method 600 may generate pad openings 62 that expose pads 60 of a top metal layer 16a of the redistribution structure 14. Further, the manufacturing method 600 may generate edge connect openings 72 that expose edge connects 70 of the top metal layer 16a of the redistribution structure 14. The manufacturing method 600 may also generate trench openings 92 that expose one or more layers of the redistribution structure 14. To this end, the manufacturing method 600 may use photolithography techniques to develop a mask over the top dielectric layer 18a and etch the top dielectric layer 18a through openings in the mask which forms pad openings 62, edge connect openings 72, and trench openings 92. In other embodiments, the manufacturing method 600 may use other techniques such as laser ablation to form openings 62, 72, 92 in dielectric layer 18a. Moreover, in some embodiments, the manufacturing method 600 may forego forming trench openings 92 and simply form a trench 100 as discussed below at 630 without first creating trench openings 92.

The manufacturing method 600 at 630 may form a trench 100 along one or more of the dicing streets 30. In particular, the trench 100 may extend through one or more metal layers 16 and/or dielectric layers 18 of the redistribution structure 14. In some embodiments, the trench 100 may extend into a top side of the substrate 12 as shown in FIG. 5B. To this end, the manufacturing method 600 may perform a deep etching process that undercuts the silicon of the silicon-on-insulator substrate 12. In some embodiments, the deep etching process may extend the trench 100 to a depth of 100 μm or greater.

At 640, the manufacturing method 600 may provide a trench sidewall metal layer 104 along sidewalls of the trench 100 as shown in FIG. 5C. In particular, the trench sidewall metal layer 104 may extend to and contact at least a portion the top metal layer 16a exposed by the edge connect openings 72. To this end, the manufacturing method 600 may provide the trench sidewall metal layer 104 using various techniques such as wafer level metal deposition or wafer level sputtering from the top side. As such, the trench sidewall metal layer 104 may effectively extend the top metal layer 16a to and along at least a portion of the photonic device sidewall. In this manner, the trench sidewall metal layer 104 may permit providing electrical connections to active devices and/or shielding components of the photonic device 20 via the photonic device sidewall.

The manufacturing method 600 at 650 may dice the wafer 10 along dicing streets 30. As shown in FIG. 5D, such dicing may cut through the trench sidewall metal layer 104 and expose the metal layer 104 at a sidewall of the photonic device 20. Various dicing techniques such as blade dicing, laser ablation dicing, and/or scribing may be used to separate the photonic devices 20 from the wafer 10. As a result of such dicing, the trench sidewall metal layer 104 may comprise a diced surface with different surface properties (e.g., rougher, blade marks, etc.) than one or more other surfaces of the trench sidewall metal layer 104. Moreover, the dicing may provide sidewall facets via which one or more photonic integrated circuit structures (e.g., photodetectors 50) of the photonic and/or electronic integrated circuit structures 40 may transmit and/or receive photons.

The manufacturing method 600 at 660 may optionally provide a sidewall metal layer 106 along the sidewall of the photonic device 20. In particular, the sidewall metal layer 106 may cover and contact a portion of the trench sidewall metal layer 104 and a portion of the substrate sidewall as shown in FIG. 5E. To this end, the manufacturing method 600 may provide the bottom side metal layer 86 using various techniques such as applying conductive epoxy along the photonic device sidewall, applying a metal coating along the photonic device sidewall, or applying the sidewall metal layer 106 via a wafer level sputtering from the substrate bottom side. As such, the trench sidewall metal layer 104 and the sidewall metal layer 106 may effectively extend the top metal layer 16a to a bottom side of the photonic device 20. In this manner, the sidewall metal layer 106 may permit providing electrical connections to active devices and/or shielding components of the photonic device 20 via the photonic device sidewall.

At 670, the manufacturing method 600 may optionally provide a bottom side metal layer 86 along a portion of the substrate bottom side. In particular, the bottom side metal layer 86 may cover and contact a bottom side of the sidewall metal layer 106. To this end, the manufacturing method 600 may provide the bottom side metal layer 86 using various techniques such as applying conductive epoxy along the substrate bottom side, applying a metal coating along the substrate bottom side, or applying the bottom side metal layer 86 via a wafer level sputtering from the substrate bottom side. As such, the trench sidewall metal layer 104, the sidewall metal layer 106, and the bottom side metal layer 86 may effectively extend the top metal layer 16a of the redistribution structure 14 to one or more portions of the photonic device bottom side. In this manner, the bottom side metal layer 86 may permit providing electrical connections to active devices and/or shielding components of the photonic device 20 via the photonic device bottom side.

The present disclosure includes reference to certain examples, however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. A photonic device, comprising:
a substrate comprising a substrate top side, a substrate bottom side, a substrate sidewall between the substrate top side and a substrate bottom side;
one or more photonic integrated circuit structures on the substrate top side, wherein the photonic integrated circuited structures include one or more photonic active devices and a redistribution structure, and wherein the redistribution structure comprises one or more dielectric layers and one or more metal layers coupled to the one or more photonic active devices;
pad openings through a first dielectric layer of the one or more dielectric layers, wherein the pad openings expose a first metal layer of the one or more metal layers at a top side of the redistribution structure; and
edge connect openings through the first dielectric layer, wherein the edge connect openings are positioned such that at least a portion of a perimeter of the first dielectric layer is closer to the edge connect openings than to the pad openings, and wherein the edge connect openings expose the first metal layer at the top side of the redistribution structure.

2. The photonic device of claim 1, wherein:
the first metal layer comprises a first metal layer sidewall; and
the edge connect openings expose the first metal layer sidewall at a sidewall of the redistribution structure.

3. The photonic device of claim 2, comprising a sidewall metal layer that coats and contacts at least a portion of the sidewall of the redistribution structure and a portion of the first metal layer sidewall.

4. The photonic device of claim 3, wherein the sidewall metal layer coats and contacts at least a portion of the substrate sidewall.

5. The photonic device of claim 3, wherein the sidewall metal layer extends from the top side of the redistribution structure to the substrate bottom side.

6. The photonic device of claim 5, comprising a bottom side metal layer that coats and contacts at least a portion of the substrate bottom side and a portion of the sidewall metal layer.

7. The photonic device of claim 1, comprising:
a trench along a perimeter edge of the redistribution structure, wherein the trench comprises a trench sidewall that extends from the top side of the redistribution structure toward the substrate top side; and
a trench sidewall metal layer that coats and contacts at least a portion of the trench sidewall, wherein the trench sidewall metal layer extends to and contacts the first metal layer via one or more edge connect openings.

8. The photonic device of claim 7, comprising a sidewall metal layer that coats and contacts at least a portion of a sidewall of the redistribution structure and a portion of the trench sidewall metal layer.

9. The photonic device of claim 8, wherein the sidewall metal layer coats and contacts at least a portion of the substrate sidewall.

10. The photonic device of claim 9, wherein the sidewall metal layer extends from the trench sidewall metal layer to the substrate bottom side.

11. The photonic device of claim 10, comprising a bottom side metal layer that coats and contacts at least a portion of the substrate bottom side and a portion of the sidewall metal layer.

12. The photonic device of claim 1, comprising:
a shielding component coupled to the first metal layer; and
wherein the shielding component reduces crosstalk between a first photonic active device and a second photonic active device of the one or more active photonic devices.

13. The photonic device of claim 1, comprising an electromagnetic interference (EMI) shielding component that at least partially surrounds a photonic active device of the one or more photonic active devices.

14. A method of fabrication a photonic device, the method comprising:
providing a wafer comprising a substrate, one or more photonic active devices on the substrate, and a redistribution structure coupled to the one or more photonic active devices;
providing pad openings and edge connect openings through a dielectric layer of the redistribution structure to expose a metal layer of the redistribution structure;
dicing through the substrate and the redistribution structure along dicing streets to separate the photonic device from the wafer; and
forming a sidewall metal layer over the photonic device such that the sidewall metal layer contacts the metal layer exposed by one or more of the edge connect openings.

15. The method of claim 14, wherein:
each edge connect opening of the edge connect openings traverses a dicing street of the dicing streets; and
dicing along the dicing streets comprises dicing through the metal layer and forming a diced sidewall of the metal layer at a sidewall of the redistribution structure.

16. The method of claim 14, comprising forming trenches along one or more of the dicing streets prior to dicing along the dicing streets.

17. The method of claim 16, wherein forming the sidewall metal layer comprises forming the sidewall metal layer such that the sidewall metal layer covers and contacts portions of trench sidewalls and an exposed portion of the metal layer of the redistribution structure.

18. The method of claim 14, comprising forming a bottom side metal layer over at least a portion of a bottom side of the photonic device such that the bottom side metal layer contacts the sidewall metal layer.

19. The method of claim 14, wherein the metal layer is coupled to a shielding component of the photonic device.

20. The method of claim 14, wherein providing the wafer comprises providing an electromagnetic interference (EMI) shielding component that at least partially surrounds a photonic active device of the one or more photonic active devices.
